(19) United States
(12) Patent Application Publication
(10) Pub. No.: US 2012/0050976 A1
(43) Pub. Date: Mar. 1, 2012

(54) SERVER ENCLOSURE

(75) Inventor: LI-PING CHEN, Tu-Cheng (TW)

(73) Assignee: HON HAI PRECISION INDUSTRY CO., LTD., Tu-Cheng (TW)

(21) Appl. No.: 13/039,273

(22) Filed: Mar. 2, 2011

(30) Foreign Application Priority Data
Aug. 24, 2010 (CN) 201010261568.0

(51) Int. Cl. H05K 7/00

(52) U.S. Cl. 361/679.32

(57) ABSTRACT

A server enclosure includes a chassis and a storage module. The chassis has at least one hook to hold the storage module. The storage module includes a mounting bracket mounted in the chassis, a riser card secured to the mounting bracket, and a memory card connected to the riser card. An opening and at least one slot are defined in the mounting bracket. The riser card has a memory card socket receiving the memory card. The memory card is inserted into the memory card socket via the opening. The at least one hook is engaged in the at least one slot to hold the storage module in the chassis.

### BACKGROUND

1. Technical Field

The present disclosure relates to a server enclosure with a storage module mounted therein.

2. Description of Related Art

Computing devices (e.g., personal computer, server) include a chassis, a motherboard mounted in the chassis, and a plurality of storage devices installed in the chassis. The storage devices include random-access memories (RAM), disk drives, and removable memory cards. The memory cards are non-volatile and offer fast read access times and better kinetic shock resistance over hard disks. To mount the memory cards, one or more metallic holders are secured in the chassis. The memory card can be mounted in the metallic holder and communicate with the motherboard. However, the metallic holder is secured by screws, which does not facilitate users to attach or detach the metallic holder.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of a server enclosure in accordance with an embodiment.

FIG. 2 is similar to FIG. 1, but viewed from another aspect.

FIG. 3 is an enlarged view of a storage module of FIG. 1.

FIG. 4 is similar to FIG. 3, but viewed from another aspect.

FIG. 5 is a pre-assembled view of FIG. 1.

FIG. 6 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

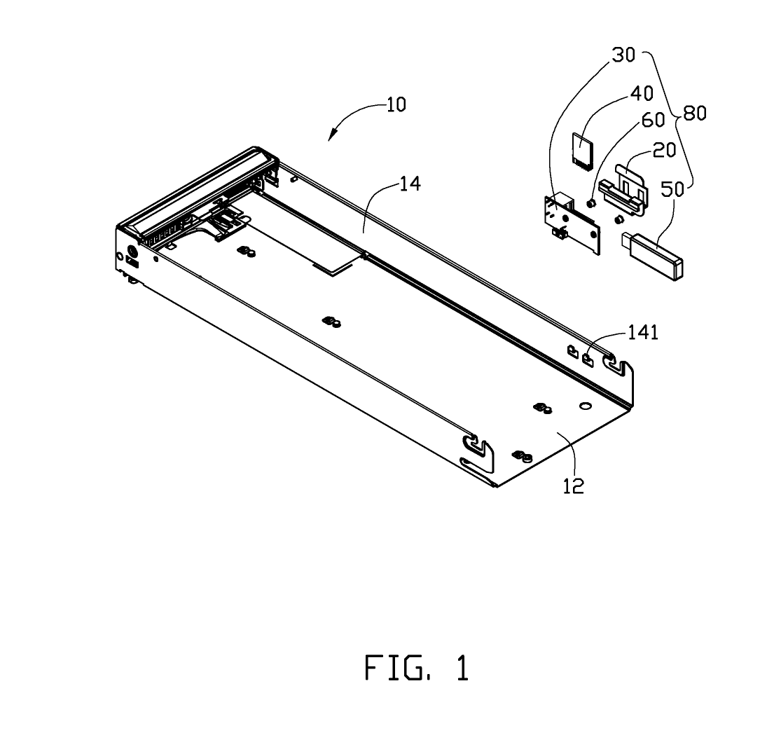

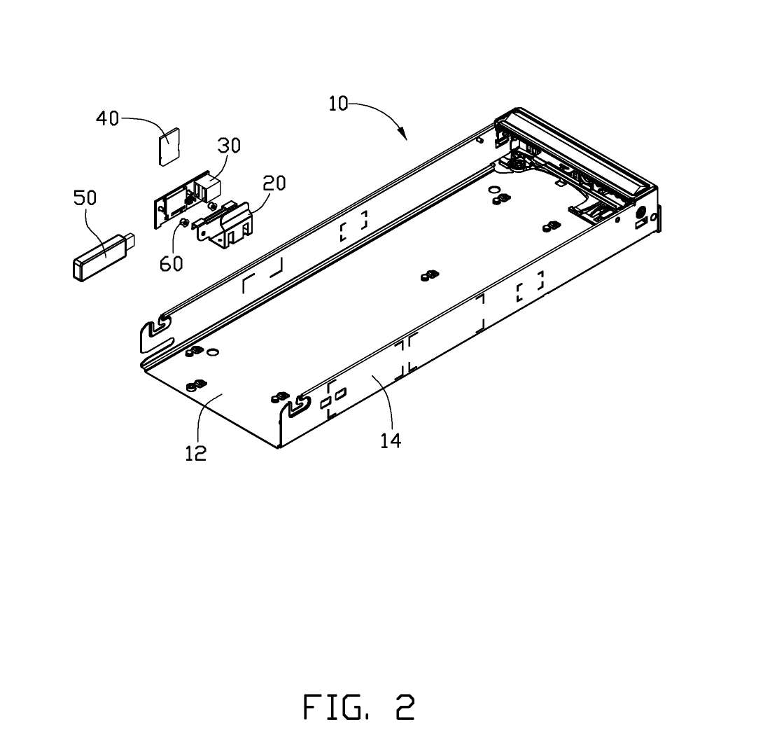

Referring to FIGS. 1 and 2, an embodiment of a server enclosure includes a chassis 10 and a storage module 80. The storage module 80 includes a mounting bracket 20, a riser card 30, a memory card 40, and a USB storage device 50.

The chassis 10 includes a bottom panel 12 and a pair of side panels 14 perpendicularly connected to the bottom panel 12. A pair of hooks 141 extends from one of the side panels 14.

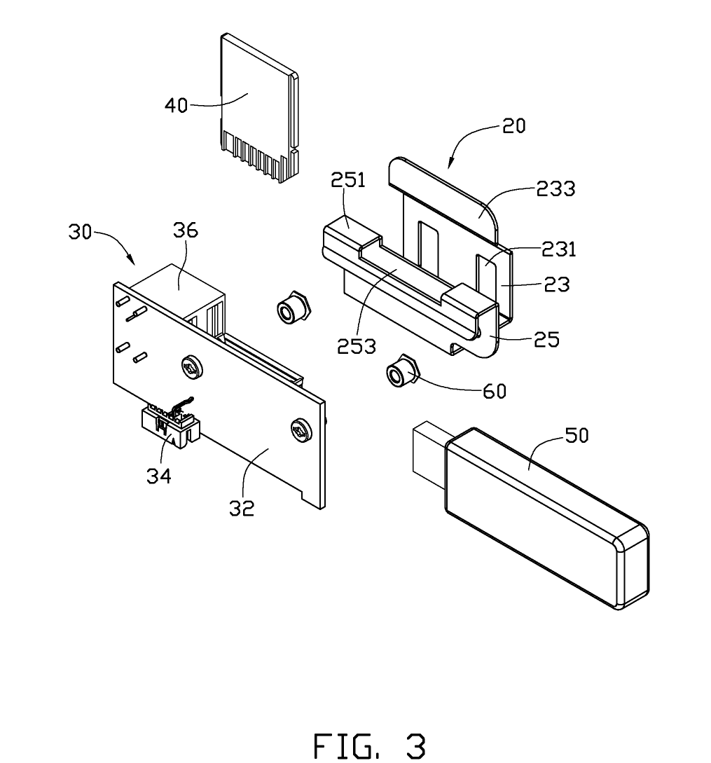

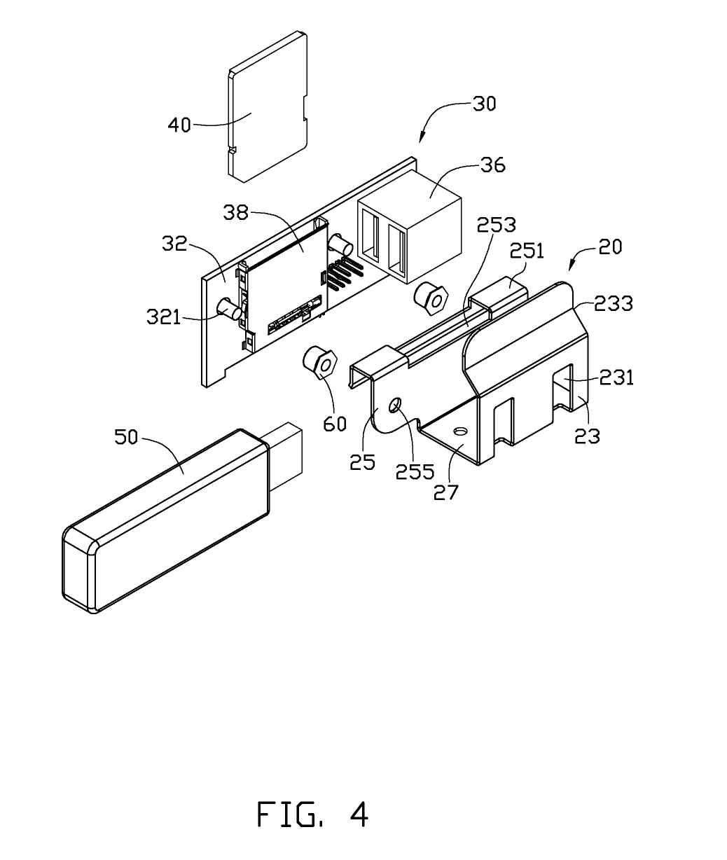

Referring to FIGS. 3-4, the mounting bracket 20 includes a first side plate 23, a second side plate 25, and a bottom plate 27 located between the first side plate 23 and the second side plate 25. A pair of L-shaped retaining slots 231 is defined in the mounting bracket 20 for engaging with the hooks 141 of the chassis 10. An upper portion of each of the retaining slots 231 is defined in the first side plate 23. A lower portion of each of the retaining slots 231 is defined in the bottom plate 27. A handle piece 233 extends upward from the first side plate 23. An L-shaped flange 251 extends from an upper edge of the second side panel 25. An opening 253 is defined in the flange 251 of the second side plate 25. A pair of securing holes 255 is defined in the second side plate 25.

The riser card 30 includes a base board 32, a connector 34, a USB socket 36, and a memory card socket 38. The connector 34 is mounted on a first side of the base board 32. The USB socket 36 and the memory card socket 38 are mounted on a second side of the base board 32. The connector 34 connects the riser card 30 to a motherboard (not shown) mounted in the chassis 10. The USB socket 36 receives a Universal Serial Bus (USB) storage device 50. The memory card socket 38 receives a memory card 40. A pair of fasteners 321 is attached to the base board 32.

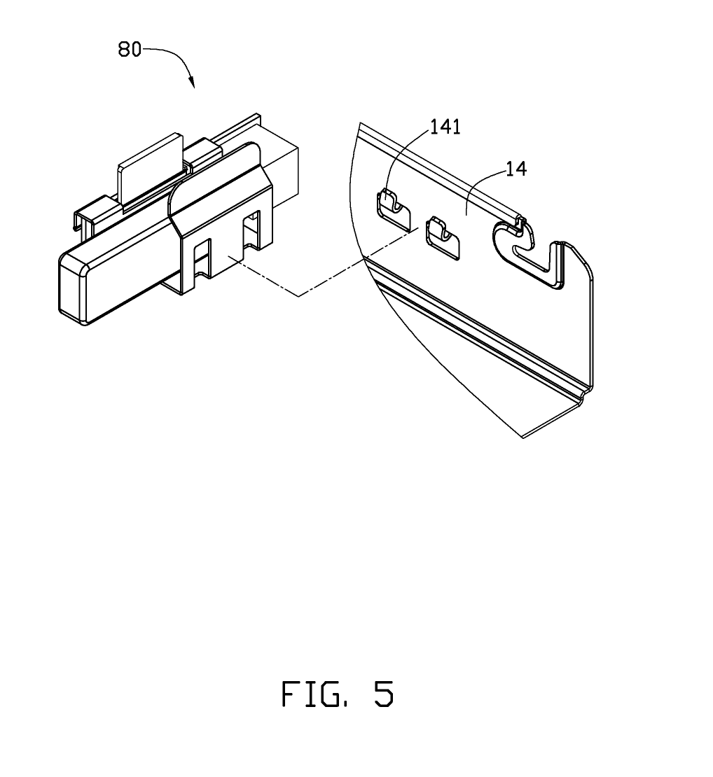

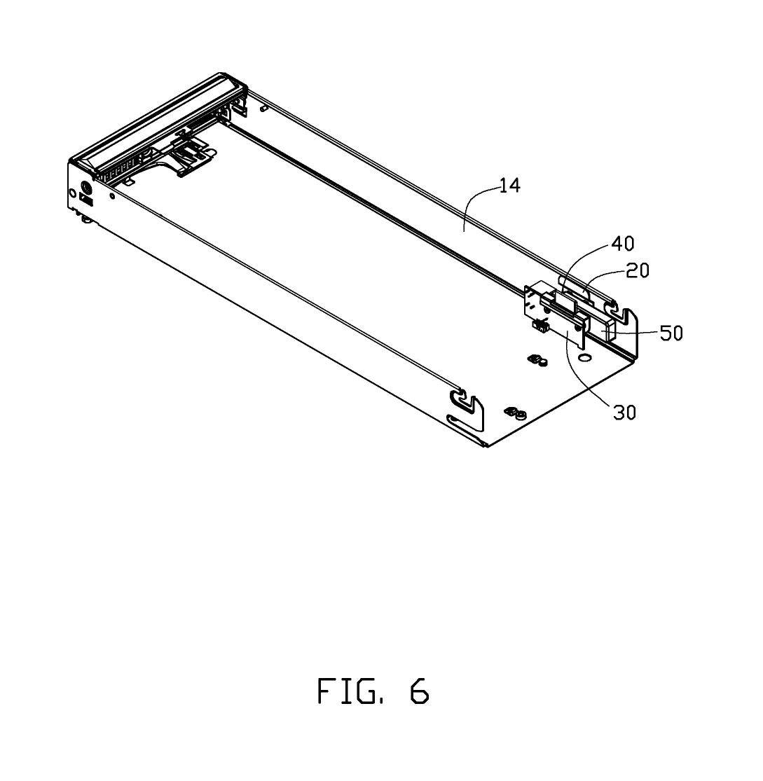

Referring to FIGS. 5 and 6, in assembly, a top of the riser card 30 abuts against the underside of the flange 251 of the mounting bracket 20. The pair of fasteners 321 engages in the securing holes 255 of the mounting bracket 20. A pair of fastener caps 60 attaches to the distal ends of the pair of fasteners 321. Then the riser card 30 securely attaches on an exterior side of the second side plate 25 of the mounting bracket 20. The memory card socket 38 of the riser card 30 is located below and aligned with the opening 253 of the mounting bracket 20. The memory card 40 is inserted into the memory card socket 38 via the opening 253 of the mounting bracket 20 along a vertical direction substantially parallel to the riser card 30. The USB storage device 50 is inserted into the USB socket 36 along a horizontal direction substantially parallel to the riser card 30. Then, the storage module 80 is assembled. The hooks 141 of the chassis 10 are engaged into the retaining slots 231 of the mounting bracket 20. The storage module 80 slides downwards until the hooks 141 of the chassis 10 abuts top edges of the retaining slots 231.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A server enclosure comprising:
a chassis with at least one hook; and
a storage module comprising a mounting bracket mounted in the chassis, a riser card secured to the mounting bracket, and a memory card connected to the riser card; an opening and at least one slot being defined in the mounting bracket, the riser card comprising a memory card socket configured to receive the memory card;
wherein the memory card is engaged in the opening and the memory card socket, and the at least one hook is engaged in the at least one slot to hold the storage module in the chassis.

2. The server enclosure of claim 1, wherein the mounting bracket comprises a first side plate, a second side plate, and a bottom plate located between the first side plate and the second side plate; and the riser card is attached to an outer side of the second side plate.

3. The server enclosure of claim 2, wherein an upper portion of the at least one slot is defined in the first side plate, and a lower portion of the at least one slot is defined in the bottom plate.

4. The server enclosure of claim 3, wherein the at least one slot has an L-shape.

5. The server enclosure of claim 2, wherein the mounting bracket further comprises a handle piece extending from the first side plate.

6. The server enclosure of claim 2, wherein the mounting bracket further comprises a flange extending from an upper edge of the second side plate, and the opening is defined in the flange.

7. The server enclosure of claim 1, wherein the riser card comprises a base board and a USB socket, and the memory card socket and the USB socket are attached to the base board.

8. The server enclosure of claim 7, wherein the memory card socket is aligned with the opening for receiving the memory card along a first direction.

9. The server enclosure of claim 8, wherein the storage module further comprises a USB storage device detachably attached to the USB socket in a second direction perpendicular to the first direction.

10. A server enclosure comprising:
a storage module comprising a mounting bracket, a riser card attached to the mounting bracket, a memory card socket attached on the riser card, and a memory card detachably attached to the memory card socket in a first direction parallel to the riser card; and at least one slot being defined in the mounting bracket; and
a chassis comprising a bottom panel, a pair of side panels connected to the bottom panel, and at least one hook extending from one of the pair of side panels; and the at least one hook engaging with a top edge of the at least one slot and holding the storage module in the chassis.

11. The server enclosure of claim 10, wherein the mounting bracket comprises a first side plate, a second side plate, and a bottom plate located between the first side plate and the second side plate; and the riser card is attached to an outer side of the second side plate.

12. The server enclosure of claim 11, wherein an upper portion of the at least one slot is defined in the first side plate, and a lower portion of the at least one slot is defined in the bottom plate.

13. The server enclosure of claim 11, wherein the mounting bracket further comprises a handle piece extending from the first side plate.

14. The server enclosure of claim 11, wherein the mounting bracket further comprises a flange extending from an upper edge of the second side plate, an opening is defined in the flange, and the memory card is engaged in the opening.

15. The server enclosure of claim 14, wherein the memory card socket is aligned with the opening.

16. The server enclosure of claim 10, wherein the riser card comprises a base board and a USB socket attached on the base board, the storage module further comprises a USB storage device detachably attached to the USB socket in a second direction parallel to the riser card along a second direction parallel to the riser card.

17. The server enclosure of claim 16, wherein the first direction is perpendicular to the second direction.
